(19) United States
(12) Patent Application Publication
(10) Pub. No.: US 2019/0235394 A1
(43) Pub. Date: Aug. 1, 2019

(54) METHOD OF PATTERNING AT LEAST A LAYER OF A SEMICONDUCTOR DEVICE

(71) Applicant: ASML NETHERLANDS B.V., Veldhoven (NL)

(72) Inventors: Reinder Teun PLUG, Eindhoven (NL); Maurits VAN DER SCHAAR, Eindhoven (NL)

(73) Assignee: ASML NETHERLANDS B.V., Veldhoven (NL)

(21) Appl. No.: 16/257,656

(22) Filed: Jan. 25, 2019

(30) Foreign Application Priority Data
Jan. 30, 2018 (EP) 18154231

(51) Int. Cl. G03F 7/20; G03F 9/00

(52) U.S. Cl. CPC G03F 7/70625; G03F 7/7015; G03F 7/70683; G03F 9/7076; G03F 7/70633; G03F 9/7088

(57) ABSTRACT

A method of patterning of at least a layer in a semiconductor device, the method including a patterning step by a patterning means, wherein the patterned layer comprises sensing radiation transmissive portions and sensing radiation blocking portions.

This application claims the benefit of priority of European Patent Application No. EP18154231, filed Jan. 30, 2018, which is incorporated herein in its entirety by reference.

### FIELD

The present description to a method of patterning for use in a lithographic process. The present description also relates to an apparatus for use in a method of patterning for use in a lithographic process.

### BACKGROUND

A lithographic apparatus is a machine that applies a desired pattern onto a substrate, usually onto a target portion of the substrate. A lithographic apparatus can be used, for example, in the manufacture of integrated circuits (ICs). In such a case, a patterning device, which is alternatively referred to as a mask or a reticle, may be used to generate a circuit pattern to be formed on an individual layer of the IC. This pattern can be transferred onto a target portion (e.g. including part of, one, or several dies) on a substrate (e.g. a silicon wafer). Transfer of the pattern is typically via imaging onto a layer of radiation-sensitive material (resist) provided on the substrate. In general, a single substrate will contain a network of adjacent target portions that are successively patterned. Conventional lithographic apparatuses include so-called steppers, in which each target portion is irradiated by exposing an entire pattern onto the target portion at once, and so-called scanners, in which each target portion is irradiated by scanning the pattern through a radiation beam in a given direction (the “scanning”-direction) while synchronously scanning the substrate parallel or anti-parallel to this direction. It is also possible to transfer the pattern from the patterning device to the substrate by imprinting the pattern onto the substrate.

As semiconductor manufacturing processes continue to advance, the dimensions of device elements (e.g., circuit elements) have continually been reduced while the amount of functional elements, such as transistors, per device has been steadily increasing over decades, following a trend commonly referred to as ‘Moore's law’. To keep up with Moore's law the semiconductor industry is chasing technologies that enable to create increasingly smaller features. To project a pattern on a substrate a lithographic apparatus may use electromagnetic radiation. The wavelength of this radiation determines the minimum size of features which are patterned on the substrate. Typical wavelengths currently in use are 365 nm (i-line), 248 nm, 193 nm and 13.5 nm. A lithographic apparatus, which uses extreme ultraviolet (EUV) radiation, having a wavelength within a range of 4 nm to 20 nm, for example 6.7 nm or 13.5 nm, may be used to form smaller features on a substrate than a lithographic apparatus which uses, for example, radiation with a wavelength of 193 nm.

The manufacturing of devices, such as ICs, typically involves the creation of a plurality of overlaying patterned layers each having an individual pattern. Each layer should be aligned as good as possible with respect to one or more other layers. In general, layer-to-layer alignment, i.e., alignment between a first layer and a second layer that overlays the previous layer, is a significant parameter representative for the functionality and/or performance of the device. A measure for the alignment between layers, or, more generally, the alignment of an individual layer with respect to a reference, may be obtained by a metrology tool, such as for example a substrate alignment sensor or an overlay metrology sensor as respectively disclosed in U.S. Pat. No. 6,961,116 and PCT patent application publication no. WO 2011/012624, each of which is incorporated herein in its entirety by reference. Such a sensor typically uses visible light reflected and/or scattered from metrology marks, for example alignment marks, overlay mark structures or product structures in the individual layers. A plurality of metrology marks are formed during the lithographic manufacturing process of the individual patterned layers and are normally placed in an area surrounding the product structures, which area is also named a scribe lane.

### SUMMARY

There is a continuing trend of utilizing one or more material layers in the manufacturing process that are not transparent for visible light, for example metal or carbon layers or new chalcogenide type of materials for 3D memory applications. Furthermore, the materials are generally not transparent to most of the available sensing radiation, such as visible, such as short wavelength radiation, such as EUV or x-ray, such as longer wavelength radiation, or such as infrared radiation. A drawback of these opaque layers is that metrology marks or other structures created in a layer, which are overlaid by an opaque layer, are not detectable or measurable by conventional metrology tools that utilize visible light, or other types of sensing radiation as mentioned above, for detecting such metrology marks or other structures. In other words, the marks or structures are obscured by the overlaying opaque layer.

In a lithographic apparatus or in a metrology apparatus, sensors are usually provided to measure the position, orientation and/or deformation of a substrate in order to accurately transfer a pattern to a target portion on the substrate. Typically, these sensors use sensor targets provided on the substrate, but when these sensor targets are covered by a layer with unfavourable properties for the sensor, e.g. the layer is opaque for an optically based sensor, the measurements are affected in a negative way, for example receiving a too low signal.

In an embodiment, these sensor targets are revealed by clearing out, or removing, a part of the opaque layer using additional lithographic and etching processing steps. These additional processing steps take a lot of time and cost a lot of machine capacity and may result in yield loss.

Furthermore, for overlay metrology applications, removing material opaque to sensing radiation may lead to a resist layer which is not uniform, which is not able to form, or which is not suitable to allow, reliable overlay measurements. In order to preserve the properties of the resist layer, an additional step may be needed such that the cleared area, as described in the process above, is filled with a material which is 1) transmissive to sensing radiation and 2) helps assure a uniform resist layer. Such an additional step, while allowing appropriate metrology measurements in terms of accuracy and/or precision, may be prohibitively expensive.

According to an embodiment, there is provided a method of patterning of at least a layer in a device (such as a semiconductor device), the method comprising a patterning step by patterning means to create a patterned layer, wherein the patterned layer comprises sensing radiation transmissive portions and sensing radiation blocking portions.

Such a patterned layer allows a) sufficient radiation to illuminate any buried or underlying grating while allowing sufficient radiation to be redirected (e.g., reflected) back such that a meaningful metrology measurement may be performed and b) a good support for a top layer of resist such that the resist layer does not bend or buckle or substantially deform, in which case also allowing meaningful metrology measurements. Meaningful metrology measurements are achieved when one determines accurately overlay or any other lithographic process parameter of interest, or substrate alignment information. An additional or alternative advantage of the method may be that the remaining patterned layer prevents further material stress release, stress which may affect negatively the overlay metrology measurement. As the pattern layer allows forming of a uniform resist layer despite having its structure patterned, further re-working (stripping of resist, re-deposition of resist, re-pattern, and re-develop) is possible and without loss of yield.

According to an embodiment, there is provided an apparatus adapted to execute the method just described wherein the patterning means comprises a laser.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a lithographic apparatus according to an embodiment;

FIG. 2 schematically depicts a clearing out device according to an embodiment;

FIG. 3A depicts a top view of a substrate covered with a layer of material;

FIG. 3B depicts a cross-sectional view of the substrate of FIG. 3A;

FIG. 4A depicts a top view of the substrate of FIG. 3A after clearing out features in the second areas;

FIG. 4B depicts in more detail a first region of the substrate of FIG. 4A;

FIG. 4C depicts in more detail a second region of the substrate of FIG. 4A;

FIG. 5A depicts a top view of the substrate of FIG. 4A after clearing out a sensor target in the first areas;

FIG. 5B depicts in more detail a third region of the substrate of FIG. 5A;

FIG. 6 depicts a cross-sectional view of the third region of the substrate of FIG. 5A;

FIG. 7 depicts a cross-sectional view of the third region of the substrate of FIG. 5A after being filled with another material; and

FIGS. 8A and 8B depict an arrangement of an overlay metrology target according to an embodiment, wherein FIG. 8A is a top view and FIG. 8B is a cross section along the line AA′.

### DETAILED DESCRIPTION

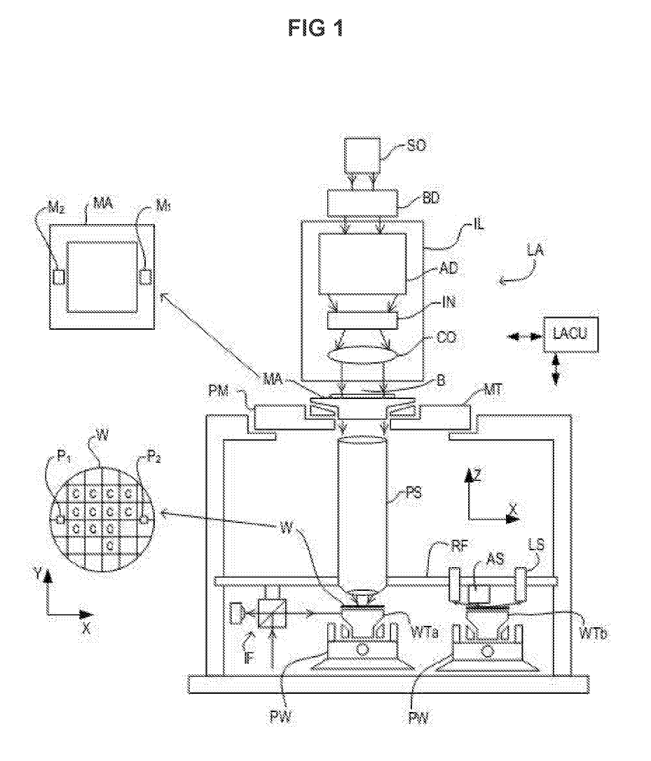

FIG. 1 schematically depicts a lithographic apparatus according to one embodiment of the invention. The apparatus comprises:

an illumination system (illuminator) IL configured to condition a radiation beam B (e.g. UV radiation or EUV radiation).

a support structure (e.g. a mask table) MT constructed to support a patterning device (e.g. a mask) MA and connected to a first positioner PM configured to accurately position the patterning device in accordance with certain parameters;

a substrate table (e.g. a wafer table) WTa or WTb constructed to hold a substrate (e.g. a resist-coated wafer) W and connected to a second positioner PW configured to accurately position the substrate in accordance with certain parameters; and

a projection system (e.g. a refractive projection lens system) PS configured to project a pattern imparted to the radiation beam B by patterning device MA onto a target portion C (e.g. comprising one or more dies) of the substrate W.

The illumination system may include various types of optical components, such as refractive, reflective, magnetic, electromagnetic, electrostatic or other types of optical components, or any combination thereof, for directing, shaping, and/or controlling radiation.

The support structure MT holds the patterning device MA in a manner that depends on the orientation of the patterning device MA, the design of the lithographic apparatus, and other conditions, such as for example whether or not the patterning device MA is held in a vacuum environment. The support structure MT can use mechanical, vacuum, electrostatic or other clamping techniques to hold the patterning device MA. The support structure MT may be a frame or a table, for example, which may be fixed or movable as required. The support structure MT may ensure that the patterning device MA is at a desired position, for example with respect to the projection system PS. Any use of the terms “reticle” or “mask” herein may be considered synonymous with the more general term “patterning device.”

The term “patterning device” used herein should be broadly interpreted as referring to any device that can be used to impart a radiation beam with a pattern in its cross-section such as to create a pattern in a target portion of the substrate W. It should be noted that the pattern imparted to the radiation beam may not exactly correspond to the desired pattern in the target portion of the substrate W, for example if the pattern includes phase-shifting features or so called assist features. Generally, the pattern imparted to the radiation beam will correspond to a particular functional layer in a device being created in the target portion, such as an integrated circuit.

The patterning device MA may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam which is reflected by the mirror matrix.

The terms “radiation” and “beam” used herein encompass all types of electromagnetic radiation, including ultraviolet (UV) radiation (e.g. having a wavelength of or about 365, 248, 193, 157 or 126 nm) and extreme ultraviolet (EUV) radiation (e.g. having a wavelength in the range of 5-20 nm), as well as particle beams, such as ion beams or electron beams.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

As here depicted, the apparatus is of a transmissive type (e.g. employing a transmissive mask). Alternatively, the apparatus may be of a reflective type (e.g. employing a programmable mirror array of a type as referred to above, or employing a reflective mask).

The lithographic apparatus may be of a type having two (dual stage) or more substrate tables (and/or two or more patterning device tables). In such “multiple stage” machines the additional tables may be used in parallel, or preparatory steps may be carried out on one or more tables while one or more other tables are being used for exposure. The two substrate tables WTa and WTb in the example of FIG. 1 are an illustration of this. An embodiment of the invention disclosed herein can be used in a stand-alone fashion, but in particular it can provide additional functions in the pre-exposure measurement stage of either single- or multi-stage apparatuses.

The lithographic apparatus may also be of a type wherein at least a portion of the substrate W may be covered by a liquid having a relatively high refractive index, e.g. water, so as to fill a space between the projection system PS and the substrate W. An immersion liquid may also be applied to other spaces in the lithographic apparatus, for example, between the patterning device MA and the projection system PS. Immersion techniques are well known in the art for increasing the numerical aperture of projection systems. The term “immersion” as used herein does not mean that a structure, such as a substrate W, must be submerged in liquid, but rather only means that liquid is located between the projection system PS and the substrate W during exposure.

Referring to FIG. 1, the illuminator IL receives a radiation beam from a radiation source SO. The radiation source SO and the lithographic apparatus may be separate entities, for example when the radiation source SO is an excimer laser. In such cases, the radiation source SO is not considered to form part of the lithographic apparatus and the radiation beam is passed from the radiation source SO to the illuminator IL with the aid of a beam delivery system BD comprising, for example, suitable directing mirrors and/or a beam expander. In other cases the source may be an integral part of the lithographic apparatus, for example when the source is a mercury lamp. The radiation source SO and the illuminator IL, together with the beam delivery system BD if required, may be referred to as a radiation system.

The illuminator IL may comprise an adjuster AD for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as an integrator IN and a condenser CO. The illuminator may be used to condition the radiation beam, to have a desired uniformity and intensity distribution in its cross-section.

The radiation beam B is incident on the patterning device MA (e.g., mask), which is held on the support structure MT (e.g., mask table), and is patterned by the patterning device MA. Having traversed the patterning device MA, the radiation beam B passes through the projection system PS, which focuses the beam onto a target portion C of the substrate W. With the aid of the second positioner PW and position sensor IF (e.g. an interferometric device, linear encoder or capacitive sensor), the substrate table WTa/WTb can be moved accurately, e.g. so as to position different target portions C in the path of the radiation beam B. Similarly, the first positioner PM and another position sensor (which is not explicitly depicted in FIG. 1) can be used to accurately position the patterning device MA with respect to the path of the radiation beam B, e.g. after mechanical retrieval from a mask library, or during a scan. In general, movement of the support structure MT may be realized with the aid of a long-stroke module (coarse positioning) and a short-stroke module (fine positioning), which form part of the first positioner PM. Similarly, movement of the substrate table WTa/WTb may be realized using a long-stroke module and a short-stroke module, which form part of the second positioner PW. In the case of a stepper (as opposed to a scanner) the support structure MT may be connected to a short-stroke actuator only, or may be fixed. Patterning device MA and substrate W may be aligned using patterning device alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device MA, the patterning device alignment marks M1, M2 may be located between the dies.

The depicted apparatus can at least be used in scan mode, in which the support structure MT and the substrate table WTa/WTb are scanned synchronously while a pattern imparted to the radiation beam is projected onto a target portion C (i.e. a single dynamic exposure). The velocity and direction of the substrate table WTa/WTb relative to the support structure MT may be determined by the (de)-magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion.

In addition to the scan mode, the depicted apparatus could be used in at least one of the following modes:
1. In step mode, the support structure MT and the substrate table WTa/WTb are kept essentially stationary, while an entire pattern imparted to the radiation beam is projected onto a target portion C at one time (i.e. a single static exposure). The substrate table WTa/WTb is then shifted in the X and/or Y direction so that a different target portion C can be exposed. In step mode, the maximum size of the exposure field limits the size of the target portion C imaged in a single static exposure.
2. In another mode, the support structure MT is kept essentially stationary holding a programmable patterning device, and the substrate table WTa/WTb is moved or scanned while a pattern imparted to the radiation beam is projected onto a target portion C. In this mode, generally a pulsed radiation source is employed and the programmable patterning device is updated as required after each movement of the substrate table WTa/WTb or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

In an embodiment, the lithographic apparatus LA is of a so-called dual stage type which has two substrate tables WTa and WTb and two stations—an exposure station and a measurement station—between which the substrate tables can be exchanged. While one substrate on one substrate table is being exposed at the exposure station, another substrate can be loaded onto the other substrate table at the measurement station so that various preparatory steps may be carried out. The preparatory steps may include mapping the surface of the substrate using a level sensor LS and measuring the position of alignment markers on the substrate using an alignment sensor AS. This enables a substantial increase in the throughput of the apparatus. If the position sensor IF is not capable of measuring the position of the substrate table while it is at the measurement station as well as at the exposure station, a second position sensor may be provided to enable the positions of the substrate table to be tracked at both stations.

The apparatus further includes a lithographic apparatus control unit LACU which controls all the movements and measurements of the various actuators and sensors described. Control unit LACU also includes signal processing and data processing capacity to implement desired calculations relevant to the operation of the apparatus. In practice, control unit LACU will be realized as a system of many sub-units, each handling the real-time data acquisition, processing and control of a subsystem or component within the apparatus. For example, one processing subsystem may be dedicated to servo control of the substrate positioner PW. Separate units may even handle coarse and fine actuators, or different axes. Another unit might be dedicated to the readout of the position sensor IF. Overall control of the apparatus may be controlled by a central processing unit, communicating with these sub-systems processing units, with operators and with other apparatuses involved in the lithographic manufacturing process.

In lithographic processes, it is desirable to make frequent measurements of the structures created, e.g., for process control and verification. Tools to make such measurement are typically called metrology tools MT. Different types of metrology tools MT for making such measurements are known, including scanning electron microscopes or various forms of scatterometer metrology tools MT. Scatterometers are versatile instruments which allow measurements of one or more parameters of a lithographic process by having a sensor in the pupil or a conjugate plane with the pupil of the objective of the scatterometer, in which case the measurements are usually referred as pupil based measurements, or by having the sensor in the image plane or a plane conjugate with the image plane, in which case the measurements are usually referred as image or field based measurements. Such metrology tools and the associated measurement techniques are further described in U.S. patent application publication nos. US 2010-0328655, US 2011-102753, US 2012-0044470, US 2011-0249244, and US 2011-0026032 and European patent application publication no. EP 1,628,164, each of the foregoing publications is incorporated herein by reference in its entirety. The aforementioned metrology tool may measure gratings using radiation from soft x-ray and visible to near-IR wavelength range.

In an embodiment, the metrology tool MT is an angular resolved scatterometer. In such a scatterometer reconstruction methods may be applied to the measured signal to reconstruct or calculate one or more properties of the grating. Such reconstruction may, for example, result from simulating interaction of scattered radiation with a mathematical model of the target structure and comparing the simulation results with those of a measurement. One or more parameters of the mathematical model are adjusted until the simulated interaction produces a diffraction pattern similar to that observed from the real target.

In a second embodiment, the metrology tool MT is a spectroscopic scatterometer. In such a spectroscopic scatterometer, the radiation emitted by a radiation source is directed onto the target and the reflected or scattered radiation from the target is directed to a spectrometer detector, which measures a spectrum (i.e. a measurement of intensity as a function of wavelength) of the specular reflected radiation. From this data, the structure or profile of the target giving rise to the detected spectrum may be reconstructed, e.g. by Rigorous Coupled Wave Analysis and non-linear regression or by comparison with a library of simulated spectra.

In a third embodiment, the metrology tool MT is an ellipsometric scatterometer. An ellipsometric scatterometer allows for determining one or more parameters of a lithographic process by measuring scattered radiation for each of a plurality of polarization states. Such a metrology apparatus emits polarized radiation (such as linear, circular, or elliptic) by using, for example, one or more appropriate polarization filters in the illumination section of the metrology apparatus. A source suitable for the metrology apparatus may provide polarized radiation as well. Various embodiments of metrology tools are described in U.S. patent application publication nos. 2007-0296960, 2008-0198380, 2009-0168062, 2010-0007863, 2011-0032500, 2011-0102793, 2011-0188020, 2012-0044495, 2013-0162996 and 2013-0308142, each of which is incorporated herein in its entirety by reference.

In one embodiment, the metrology tool MT is adapted to measure the overlay of two misaligned gratings or periodic structures by measuring asymmetry in the reflected spectrum and/or the detection configuration, the asymmetry being related to the extent of the overlay. The two (typically overlapping) grating structures may be applied in two different layers (not necessarily consecutive layers), and may be formed substantially at the same position on the substrate. The metrology tool may have a symmetrical detection configuration as described e.g. in European patent application publication no. EP 1,628,164 (which is incorporated herein in its entirety by reference), such that any asymmetry is clearly distinguishable. This provides a straightforward way to measure misalignment in gratings. Further examples for measuring overlay error between two layers containing periodic structures as a target is measured through asymmetry of the periodic structures and may be found in PCT patent application publication no. WO 2011/012624 or U.S. patent application publication no. US 2016-0161863, each of which is incorporated herein in its entirety by reference.

Other parameters of interest may be focus and dose. Focus and dose may be determined simultaneously by scatterometry (or alternatively by scanning electron microscopy) as described in U.S. patent application publication no. US 2011-0249244, which is incorporated herein in its entirety by reference. A single structure may be used which has a unique combination of critical dimension and sidewall angle measurements for each point in a focus energy matrix (FEM—also referred to as focus exposure matrix). If these unique combinations of critical dimension and sidewall angle are available, the focus and dose values may be uniquely determined from these measurements.

A metrology target may be an ensemble of composite gratings, formed by a lithographic process, mostly in resist, but also after an etch process for example. Typically, the pitch and line-width of the structures in the gratings strongly depend on the measurement optics (in particular the numerical aperture (NA) of the optics) to be able to capture diffraction orders coming from the metrology targets. As indicated earlier, the diffracted signal may be used to determine shifts between two layers (also referred to ‘overlay’) or may be used to reconstruct at least part of the original grating as produced by the lithographic process. This reconstruction may be used to provide guidance of the quality of the lithographic process and may be used to control at least part of the lithographic process.

Targets may have smaller sub-segmentation which are configured to mimic dimensions of the functional part of the design layout in a target. Due to this sub-segmentation, the targets will behave more similar to the functional part of the design layout such that the overall process parameter measurements resemble the functional part of the design layout better.

The targets may be measured in an underfilled mode or in an overfilled mode. In the underfilled mode, the measurement beam generates a spot that is smaller than the overall target. In the overfilled mode, the measurement beam generates a spot that is larger than the overall target. In such an overfilled mode, it may also be possible to measure different targets simultaneously, thus determining different processing parameters at the same time.

Overall measurement quality of a lithographic parameter using a specific target is at least partially determined by the measurement recipe used to measure this lithographic parameter. The term “substrate measurement recipe” may include one or more parameters of the measurement itself, one or more parameters of the one or more patterns measured, or both. For example, if the measurement used in a substrate measurement recipe is a diffraction-based optical measurement, one or more of the parameters of the measurement may include the wavelength of the radiation, the polarization of the radiation, the incident angle of radiation relative to the substrate, the orientation of radiation relative to a pattern on the substrate, etc. One of the criteria to select a measurement recipe may, for example, be a sensitivity of one of the measurement parameters to processing variations. Examples are described in US patent application publication nos. US 2016-0161863 and US patent application 2016-0370717, each of which incorporated herein in its entirety by reference.

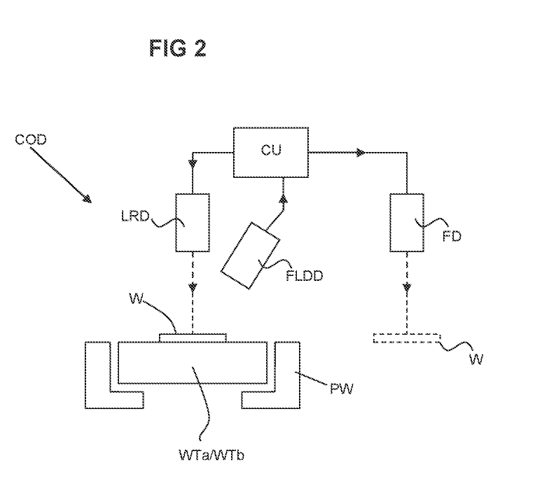

FIG. 2 schematically depicts a clearing out device COD, as described, for example in PCT patent application publication no. WO 2019-007590, which is incorporated herein in its entirety by reference. The clearing out device COD is, in this embodiment, part of the lithographic apparatus of FIG. 1 and reachable by at least one of the two tables WTa/WTb to provide a substrate W to the clearing out device COD.

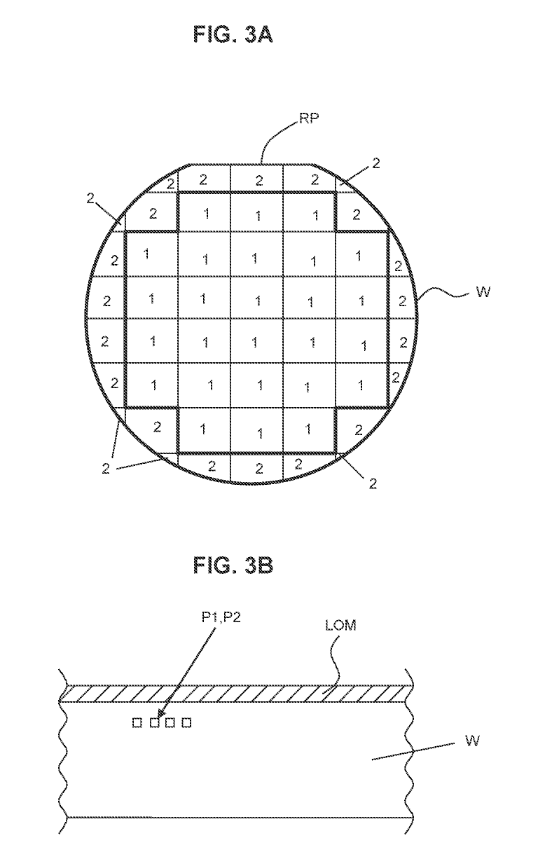

The clearing out device COD is configured to clear out one or more sensor targets on a substrate covered with a layer of material. This can be best seen by reference to FIGS. 3A and 3B. FIG. 3A schematically depicts a top view of a substrate W covered with a layer of material and FIG. 3B depicts a cross-sectional view of the substrate W. The substrate W includes one or more sensor targets, for instance a substrate alignment mark P1 or P2, e.g. a grating. The substrate W is covered by a layer of material LOM, also covering the sensor target P1, P2. This layer of material LOM may impede a sensor from accurately measuring its position, e.g. by being opaque to an optically based sensor, e.g. a carbon layer as occurring in e.g. a 3D NAND process. Clearing out removes the layer of material LOM at least partially such that the sensor target can be used by a sensor apparatus. At least partially removing the layer of material LOM thus also includes an embodiment in which a thickness of the layer of material is reduced without completely removing the layer of material. Hence, the thickness of the layer of material may be reduced to a value that the layer of material becomes sufficiently transparent for an optically based sensor apparatus. At least partially removing the layer of material further also includes completely removing the layer, i.e. reducing the thickness to zero.

In order to clear out the sensor target P1,P2, the clearing out device comprises a layer removal device LRD, a feature location determination device FLDD and a filling device FD, all under control or at least in connection with a control unit CU, which may be part of the lithographic apparatus control unit LACU as described in relation to FIG. 1.

Referring to FIG. 3A again, the substrate W comprises first areas indicated by reference symbol ‘1’ with production target portions and second areas indicated by reference symbol ‘2’ with non-production target portions. Non-production target portions are target portions that are not useful to a manufacturer of e.g. integrated circuits, for instance because the target portion is at the edge of the substrate W and not complete, i.e. incomplete, as a result of which it is not possible to yield a working device. Production target portions are target portions that are useful to a manufacturer of e.g. integrated circuits and able to yield a working device.

Information about the expected location of the first areas 1 and the second areas 2 is usually directly or indirectly provided by the manufacturer as it, among other things, depends on the target portion size and the distribution of target portions across the substrate, which are all chosen and/or set by the manufacturer. The control unit CU of the clearing out device COD in FIG. 2 is configured to receive and/or store this information and to determine the location of the first and second areas 1,2 based on the information.

The substrate W comprises a reference plane RP or any other reference to allow the clearing out device COD to roughly determine the location of the target portions based on the information provided to and/or stored in the control unit CU. However, as the substrate W may be deformed and the sensor targets P1, P2 are covered by the layer of material LOM, it may not be possible to determine the position of the sensor targets P1, P2 accurately enough. This may result in a cleared out area which is not large enough to reveal the entire sensor target P1, P2, but only a part may be revealed. Hence, when clearing out the sensor target directly, it is usually required to clear out a region that is substantially larger than the sensor target, which may result in the layer of material also being removed in the first areas above product features as a result of which the product can no longer be finished and yield is reduced.

Hence, in accordance with an embodiment of the invention, regions in the second areas are cleared out first to reveal features in the second areas. The area of these regions is large enough to reveal the entire sensor target P1, P2. The control unit CU is therefore configured to control the layer removal device LRD to at least partially clear out the second areas by at least partially removing the layer covering the second areas to reveal features in the second areas. The location of the features is for instance known from a database comprising a substrate layout and locations of the features, e.g. sensor targets or other types of features, in combination with a rough indication of the substrate position.

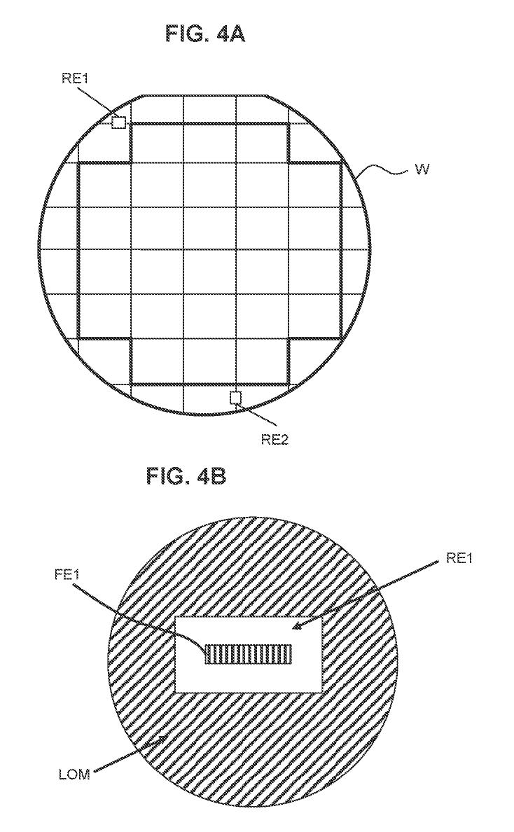

FIG. 4A depicts the substrate W of FIG. 3A, but after the layer removal device LRD has removed the layer of material at a first region RE1 and a second region RE2, which first and second regions are located in the second areas. The layer removal device may, for instance, be a laser, e.g. an ablation laser, configured to remove the layer of material by laser ablation, e.g. the laser is an ultra short pulsed laser. In this embodiment, the layer removal device LRD is stationary and the substrate W is moved below the layer removal device LRD using the table WTa/WTb and the corresponding positioner PW. Alternatively or additionally, the layer removal device LRD may be moveable. The layer may be removed by an etching process, e.g. plasma etching.

FIG. 4B depicts the first region RE1 in more detail. By removing the layer of material LOM in the first region RE1, a first feature FE1 is revealed. As can be seen, the first region RE1 is much larger than the feature FE1 as the location of the first feature FE1 can't be determined accurately enough. The size of the first region RE1 is such that within the error margin of the determination of the location of the first feature FE1, the first feature will always be revealed. The first feature FE1 may be a sensor target like the sensor target P1, P2, but may also be another mark, target, grating or any other recognizable feature.

FIG. 4C depicts the second region RE2 in more detail. By removing the layer of material LOM in the second region RE2, a second feature FE2 is revealed. As can be seen, the second region RE2 is much larger than the feature FE2 as the location of the second feature FE2 can't be determined accurately enough. The size of the second region RE2 is such that within the error margin of the determination of the location of the second feature FE2, the second feature will always be revealed. The second feature may be a sensor target like the sensor target P1, P2, but may also be another mark, target, grating or any other recognizable feature as schematically indicated here.

Once the first and second features FE1, FE2 are revealed, the feature location determination device is controlled to measure a location of the revealed features with more accuracy than initially for the clearing out process. This measurement can be used to determine the exact orientation and deformation of the substrate to determine a location of a sensor target P1, P2 in the first areas, e.g. again based on a database comprising a substrate layout and locations of sensor targets P1, P2.

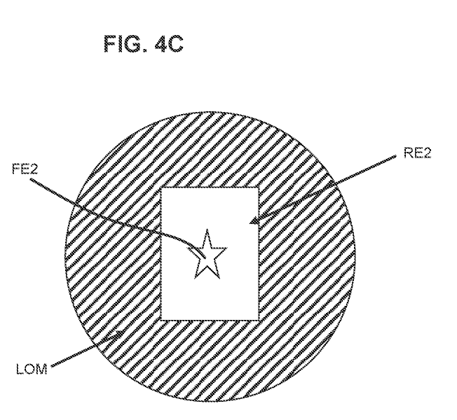

FIG. 5A depicts the substrate W of FIG. 4A, but after determining a location of a sensor target P1, P2 in the first areas based on the location of the measured first and second features, and controlling the layer removal device to clear out a third region RE3 and reveal a sensor target in the first areas by removing the layer of material covering the sensor target based on the determined location of the sensor target.

FIG. 5B depicts the third region RE3 in more detail. By removing the layer of material LOM in the third region RE3, the sensor target P1, P2 is revealed. As can be seen, the third region is only slightly larger than the sensor target P1, P2 as the location of the sensor target can be determined more accurately based on the measured locations of the first and second features. As a result, clearing out the third region will not negatively affect any neighboring target portions, so that yield is not reduced while clearing out the sensor targets.

Although FIGS. 5A and 5B only show the clearing out of the third region RE3, i.e. a single region in the first areas, it will be apparent to the skilled person that using this method, any number of sensor targets in the first areas can be cleared out.

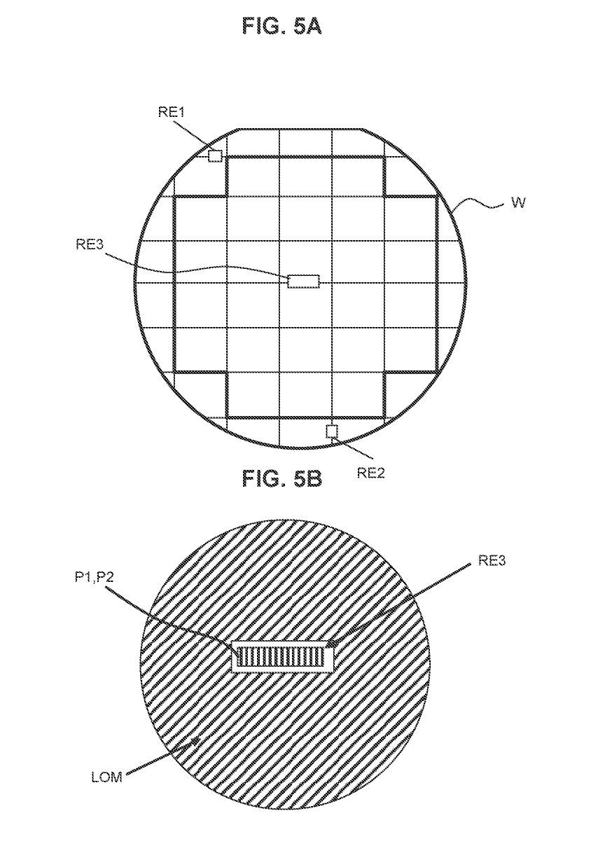

FIG. 6 depicts a cross-sectional view of the third region RE3 of the substrate W of FIG. 5A. It can be clearly seen that the layer of material LOM is removed above the sensor target P1, P2 so that the sensor of the lithographic apparatus is able to interact with the sensor target P1, P2 to determine the position of the sensor target P1, P2 accurately during subsequent processing. However, due to the clearing out process, there is a step-like structure surrounding the sensor target so that when a resist layer is provided on the substrate, a non-uniform thickness of the resist layer is obtained.

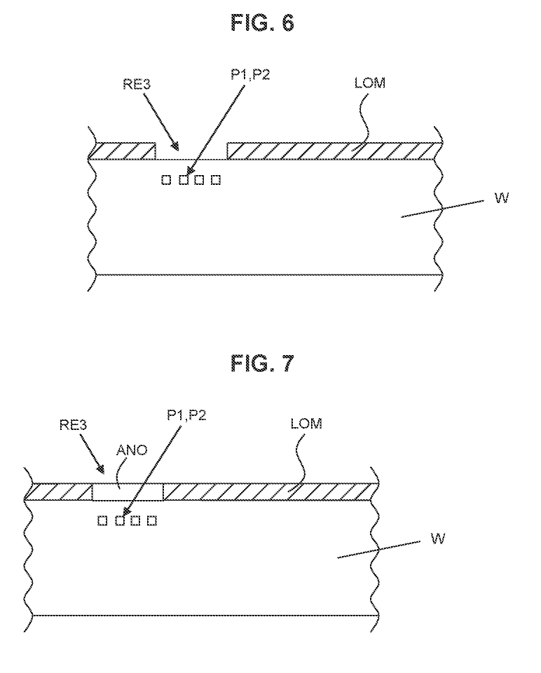

To improve this situation, the third region RE3 may first be filled with another material ANO using the filling device FD as depicted in FIG. 7, which other material is desirably chosen such that it does not impede with the location measurement of the sensor target P1, P2, but provides a flat upper surface of the substrate W to allow a resist layer to be provided on the substrate and obtain a substantially uniform thickness.

The substrate W may, for instance, be brought below the filling device FD as depicted in phantom in FIG. 2 by correspondingly positioning the substrate holder. The material ANO may, for instance, be spin coated on the substrate W in a similar manner as resist is applied to a substrate.

Despite one or more advantages of having the opening RE3 filled with a material ANO, such a process may be prohibitory expensive, when used for overlay metrology. It is a further aim to provide a patterning step of the filling material ANO such that the opaque material becomes transmissive to sensing radiation while maintaining at the same time structural stability and uniformity of any other layer which may be deposited on top.

So, in an embodiment, there is provided a method of patterning of at least a layer in a semiconductor device, the method comprising a patterning step by a patterning means to create a patterned layer, wherein the pattern layer comprises sensing radiation transmissive portions and sensing radiation blocking portions. In an embodiment the patterning means is a laser or a LED based radiation source or is a process such as etching. In the situation when the patterning means is a laser or a LED based radiation source, the patterning is achieved by ablating the material. Sensing radiation is the radiation used in a metrology process, such as an overlay metrology or a position metrology.

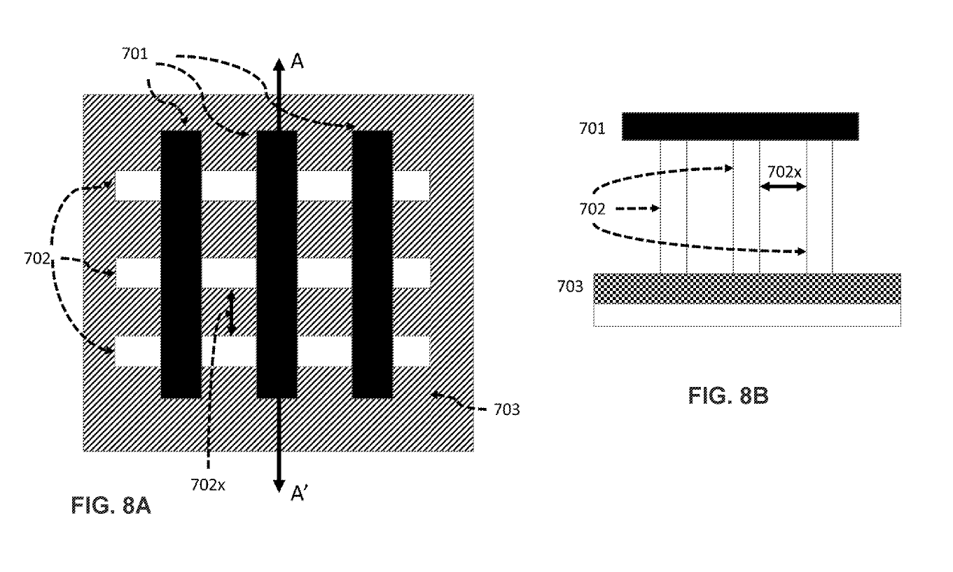

An embodiment is depicted in FIG. 8, wherein FIG. 8A is a top view and FIG. 8B is a cross-section along the line AA′ from FIG. 8A. FIG. 8A depicts patterned resist lines, such as elements 701, on top of a elements 702. Elements 702 are formed by a patterning means in a material which is opaque to sensing radiation of the metrology tool. Elements 701 are formed in resist by a lithographic process, and may form part of a metrology overlay target. It is an aim of this embodiment that the patterning means used in the patterning step may form sensing radiation transmissive areas 702x. In the exemplary embodiment of FIG. 8, it is depicted a 1D arrangement, comprising elements 702, which are formed from the material of the opaque layer, and elements 702x which is the distance between the elements 702, and which may allow the transmission of the sensing radiation. The patterning means, for example the patterned spot of a laser beam, may ablate the material of the opaque layer, creating the spacings 702x. Further, elements 702 may be sensing radiation blocking portions and elements 702x may be sensing radiation transmissive portions. Element 703 may be the bottom grating in a diffraction based target.

In an embodiment, a ratio between the sensing radiation transmissive portions 702x and sensing radiation blocking portions 702 is 30%. The ratio is defined as the area of the sensing radiation transmissive portion divided by the total patterned area. The ratio may also be defined as the area of a single element of the sensing radiation transmissive portion such as 702x and the area formed by a single element of the sensing radiation transmissive portion 702x and a single element of the sensing radiation blocking portion 702. In an embodiment, the dimension of one of the sensing radiation transmission portion elements is 100 nm and the dimension of one of the sensing radiation blocking portion elements is 200 nm. In an embodiment, element 702x is 200 nm and element 702 is 100 nm, in which case the ratio between the sensing radiation transmissive portions and sensing radiation blocking portions is 67%.

In an embodiment, the ratio between the sensing radiation transmissive portions and sensing radiation blocking portions is 50%. Further, the dimension of one of the sensing radiation transmission portion elements is 100 nm and the dimension of one of the sensing radiation blocking portion elements is 100 nm. In another embodiment, the ratio between the sensing radiation transmissive portions and sensing radiation blocking portions is 70%. In an embodiment, the dimension of one of the sensing radiation transmission portion elements is 70 nm and the dimension of one of the sensing radiation blocking portion elements is 30 nm. In an embodiment, the dimension of one of the sensing radiation transmission portion elements is 140 nm and the dimension of one of the sensing radiation blocking portion elements is 60 nm. In an embodiment, element 702x is 200 nm and element 702 is 100 nm.

In an embodiment, the ratio is 50%, with a dimension of element 702x of 300 nm and a dimension of element 702 of 300 nm.

In an embodiment, the ratio between the sensing radiation transmissive portions and sensing radiation blocking portions is 50%.

In an embodiment, the ration between the sensing radiation transmissive portions and sensing radiation blocking portions is 33%.

In an embodiment, the sensing radiation transmissive portions have a geometrical symmetry, such as point symmetry (circular, ellipsoid, etc) or axis symmetry (rectangular, etc.) and may be part of a 2D (2 dimensional) pattern.

In an embodiment, the sensing radiation transmissive portions have random symmetry.

In an embodiment, the arrangement of the sensing radiation transmissive portions and sensing radiation blocking portions is random.

In an embodiment, the pattern in the hard mask is a 3D pattern. In this case the patterning step comprises 1) creating a clear area by, for example, chemical etching or laser ablation, such that the clear area clears the underlying target and 2) the deposition of a material which is porous or comprising openings such that it allows the transmission of the sensing radiation. An advantage of a 3D pattern is that it is intrinsically beneficial to the uniformity of the resist layer which is deposited on top.

In an embodiment the patterning means is a laser having a fluency of 0.5 J/cm². In an embodiment, the patterning means is a laser having a fluency of 0.1 J/cm².

The laser beam is adapted, by interferometry or holography methods, which are currently known in the art, to create a pattern similar to the resulting pattern after the patterning step. For example, if the patterning step creates a 1D pattern, then the laser beam profile may comprise a 1D profile of the intensity. For example, if the patterning step creates a 2D pattern, the laser beam profile may comprise a 2D profile of the beam intensity.

In an example, the laser spot has a diameter of 5 microns. When used to create a 1D pattern of 30% ratio between the sensing radiation transmissive portion and total portion of the patterned area, wherein the filled portion has a sensing radiation transmissive element and sensing radiation blocking element each of 300 nm, the profile of the laser spot has, in an embodiment, a sinusoidal profile of the fluency with a period of 300 nm.

Known methods to create a pattern illumination profile having sufficient fluency such that the beam may pattern the hard mask are, for example, laser ablation comprising a Lloyd's mirror, a diffractive optical element, a holographic optical element, a spatial light modulator, a LED, or a semiconductor laser.

In a further embodiment, the patterning means comprises a nanoimprint step followed by chemical etching of the hard mask.

In a further embodiment, the patterning means is an etching process preceded by a patterning process, wherein the patterning process may comprise a lithographic step or a nanoimprint step.

So, in an embodiment, there is provided a method of patterning of at least a layer in a semiconductor device, the method comprising a patterning step by a patterning means to create a patterned layer, wherein the patterned layer comprises sensing light transmissive portions and sensing light blocking portions. In an embodiment, the patterned layer comprises a 1D pattern. In an embodiment, the ratio between the sensing light transmissive portions and the sensing light blocking portions is between 25% and 50%. In an embodiment, the ratio is 30%. In an embodiment, the ratio is 50%. In an embodiment, the ratio is 70%. In an embodiment, the patterned layer comprises a 2D pattern. In an embodiment, the patterned layer comprises a 3D pattern. In an embodiment, the patterned layer is formed during the deposition of a porous material. In an embodiment, the patterning means is a laser or a LED based light source or a process such as etching.

In an embodiment, there is provided an apparatus adapted to execute a method as described herein, wherein the patterning means comprises a laser.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

Although specific reference may have been made above to the use of embodiments of the invention in the context of optical lithography, it will be appreciated that the invention may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

While specific embodiments of the invention have been described above, it will be appreciated that the invention may be practiced otherwise than as described. For example, the invention may take the form of a computer program containing one or more sequences of machine-readable instructions describing a method as disclosed above, or a data storage medium (e.g. semiconductor memory, magnetic or optical disk) having such a computer program stored therein.

The descriptions above are intended to be illustrative, not limiting. Thus, it will be apparent to one skilled in the art that modifications may be made to the invention as described without departing from the scope of the claims set out below.

1. A method of patterning of at least a layer in the formation of a device, the method comprising a patterning step involving use of a patterning device or process to create a patterned layer, wherein the patterned layer comprises sensing radiation transmissive portions and sensing radiation blocking portions.

2. The method according to claim 1, wherein the patterned layer comprises a 1D pattern.

3. The method according to claim 2, wherein a ratio between the sensing radiation transmissive portions and the sensing radiation blocking portions is greater than or equal to 25%.

4. The method according to claim 3, wherein the ratio is 30%.

5. The method according to claim 3, wherein the ratio is 50%.

6. The method according to claim 3, wherein the ratio is 70%.

7. The method according to claim 1, wherein the patterned layer comprises a 2D pattern.

8. The method according to claim 1, wherein the patterned layer comprises a 3D pattern.

9. The method according to claim 8, wherein the patterned layer is formed during deposition of a porous material.

10. The method according to claim 1, wherein the patterning step involves the use of a patterning device and the patterning device is a laser or a LED based radiation source or wherein the patterning step involves the use of a patterning process and the patterning process involves etching.

11. An apparatus, comprising:
a laser; and
a control unit configured to cause the laser to create a patterned layer in the formation of a device, wherein the patterned layer comprises sensing radiation transmissive portions and sensing radiation blocking portions.

12. The apparatus according to claim 11, wherein a ratio between the sensing radiation transmissive portions and the sensing radiation blocking portions is greater than or equal to 25%.

13. A non-transitory computer-readable medium comprising instructions therein, the instructions, when executed by a computer system, are configured to cause the computer system to at least cause performance of a patterning step involving use of a patterning device or process to create a patterned layer in the formation of a device, wherein the patterned layer comprises sensing radiation transmissive portions and sensing radiation blocking portions.

14. The computer-readable medium according to claim 13, wherein the patterned layer comprises a 1D pattern.

15. The computer-readable medium according to claim 13, wherein a ratio between the sensing radiation transmissive portions and the sensing radiation blocking portions is greater than or equal to 25%.

16. The computer-readable medium according to claim 13, wherein the patterned layer comprises a 2D pattern.

17. The computer-readable medium according to claim 13, wherein the patterned layer comprises a 3D pattern.

18. The computer-readable medium according to claim 17, wherein the patterned layer is formed during deposition of a porous material.

19. The computer-readable medium according to claim 13, wherein the patterning step involves the use of a patterning device and the instructions are further configured to cause a laser or a LED based radiation source to produce the patterned layer.

20. The computer-readable medium according to claim 13, wherein the patterning step involves the use of a patterning process and the instructions are further configured to cause performance of an ablation-type process.
